(19) United States
(12) Patent Application Publication
(10) Pub. No.: US 2016/0155844 A1
(43) Pub. Date: Jun. 2, 2016

(54) ASYMMETRIC ULTRATHIN SOI MOS TRANSISTOR STRUCTURE AND METHOD OF MANUFACTURING SAME

(71) Applicant: INSTITUTE OF MICROELECTRONICS, CHINESE ACADEMY OF SCIENCES, Beijing (CN)

(72) Inventors: Haizhou YIN, Poughkeepsie, NY (US); Keke ZHANG, Shandong (CN)

(21) Appl. No.: 14/904,711

(22) PCT Filed: Oct. 21, 2013
(86) PCT No.: PCT/CN2013/085541

§ 371 Date: Jan. 13, 2016

(30) Foreign Application Priority Data
Oct. 14, 2013 (CN) 201310478396.6

(51) Int. Cl. H01L 29/78; H01L 29/06; H01L 21/02; H01L 21/265; H01L 21/306; H01L 29/66; H01L 29/08

(52) U.S. Cl. CPC H01L 29/7835; H01L 29/66636; H01L 29/66659; H01L 29/0649; H01L 29/0847; H01L 21/26513; H01L 21/30604; H01L 21/02636; H01L 29/66545

(57) ABSTRACT

A method for manufacturing an asymmetric super-thin SOIMOS transistor is disclosed. The method comprises: a. providing a substrate composed of an insulating layer (200) and a semiconductor layer (300); b. forming a gate stack (304) on the substrate; c. removing semiconductor materials of the semiconductor layer (300) on a source region side to form a first vacancy (001); d. removing insulating materials of the insulating layer (200) in the source region and under channel near the source region to form a second vacancy (002); e. filling semiconductor materials into the first vacancy (001) and the second vacancy (002) to connect with the semiconductor materials above the second vacancy (002); and f. performing source/drain implantation. Compared with the prior art, the method of the disclosure can suppress the short channel effects and enhance device performance.

The present disclosure claims priority of Chinese patent application No. 201310478396.6 entitled “Asymmetric Super-Thin SOIMOS Transistor and Method for Manufacturing the Same” filed on Oct. 14, 2013, the entirety of which is incorporated herein by reference.

### TECHNICAL FIELD

The present disclosure relates to a semiconductor device and a method for manufacturing the same, and in particular, to an asymmetric super-thin SOIMOS transistor and a method for manufacturing the same.

### BACKGROUND

Silicon on Insulator, i.e. SOI, is generally recognized as one of the mainstream semiconductor technique in 21^{st} century. SOI technique may effectively overcome disadvantages of bulk silicon material and fully exert potential of silicon integrated circuits, and is becoming the mainstream technique for manufacturing Very Large Scale Integrated Circuits (VLSIC) with high speed, low power consumption, high integration level and high reliability.

In Metal Oxide Semiconductor Field Effect Transistor (MOSFET), it is desirable to have a channel as narrow as possible, so as to enhance control of the channel by the gate and suppress short channel effects. However, when the thickness of the channel is less than 10 nm, carrier mobility will decrease with the reduction of channel thickness, which may deteriorate device performance seriously. In particular, the portion of the channel near source end may be affected severely. While in drain end, channel width will play a minor role in carrier mobility due to the effects of saturation caused by high electric field.

Drain Induction Barrier Lower (DIBL) is a non-ideal effect in short channel devices. When channel length decreases, source-drain voltage may increase such that P-N junction depletion regions of source and drain becomes closer and electric line in channel may punch through from source to drain, which may cause decrease of potential barrier in source end and increase of carriers from source to channel and thereby lead to increase of current in drain end. With further decrease of channel length, threshold voltage of transistors may decrease due to increasingly severe DIBL effects, which may result in decrease of device voltage gain and restrict improvement of integration level of VLSIC. In order to suppress the effects of DIBL, it is desirable to have a channel width, especially the channel width near drain end, as narrow as possible.

Therefore, in order to balance the effects on career mobility and DIBL by channel width to enhance device performance, an asymmetric super-thin SOI Metal-Oxide-Semiconductor (SOIMOS) transistor and a method for manufacturing the same are provided in the present disclosure. In this SOIMOS transistor, the thickness of the channel near the source is 1-3 times the thickness near the drain, and the length of the relative thin portion of the channel is 1-3 times the length of the relative thick portion. In other words, the channel has a larger width near the source in regard of the effects on career mobility by channel width. While in a position near the drain, because the channel width has a small effect on carrier mobility, the channel has a smaller width to suppress effects of DIBL. Compared with the prior art, the present disclosure can suppress the short channel effects and enhance device performance.

### SUMMARY OF THE INVENTION

The present disclosure provides an asymmetric super-thin SOIMOS transistor and a method for manufacturing the same, which may suppress the short channel effects and enhance device performance. Specifically, the present disclosure provides a method for manufacturing an asymmetric super-thin SOIMOS transistor, comprising:

a. providing a substrate composed of an insulating layer (200) and a semiconductor layer (300);
b. forming a gate stack (304) on the substrate;
c. removing semiconductor materials of the semiconductor layer (300) on a source region side to form a first vacancy (001);
d. removing insulating materials of the insulating layer (200) in the source region and under channel near the source region to form a second vacancy (002);
e. filling semiconductor materials into the first vacancy (001) and the second vacancy (002) to connect with the semiconductor materials above the second vacancy (002); and
f. performing source/drain implantation.

Wherein in step c, the first vacancy has a length equal to that of the source region on the semiconductor layer, and has a thickness equal to that of the semiconductor laye.

Wherein in step c, the semiconductor materials of the semiconductor layer on a source region side are removed by anisotropic etching to form a first vacancy.

Wherein in step d, the second vacancy has a thickness 1-3 times that of the semiconductor layer.

Wherein in step d, the length of the vacancy extending into under the gate stack (304) is ¼-⅔ times the length of the gate stack.

Wherein in step d, the insulating materials of the insulating layer in the source region and under channel near the source region is removed by isotropic etching to form a second vacancy.

Wherein in step e, the semiconductor materials are filled into the first vacancy and the second vacancy by selective epitaxial growth.

Wherein the step b is replaced by:

g. forming a gate dielectric layer on the substrate, and forming a dummy gate structure on the gate dielectric layer; and
h. forming source/drain extension regions on both sides of the dummy gate stack.

Wherein after the step f, the method further comprises:

i. thickening the semiconductor layer on the drain region side such that the top of the drain region is flushed with the top of the source region.

Wherein after the step f, the method further comprises:

j. removing the dummy gate stack to form a dummy gate vacancy; and
k. depositing the gate stack in the dummy gate vacancy.

Accordingly, the present disclosure provides An asymmetric super-thin SOIMOS transistor, comprising:

a substrate (100);
an insulting layer (200) on the substrate (100);
a semiconductor layer (300) on the insulting layer (200);
a gate dielectric layer (301) on the semiconductor layer (300);
a gate stack (304) on the gate dielectric layer (301);
a channel region under the gate stack (304);
source/drain regions in the substrate on both sides of the gate stack (304); and
an interlayer dielectric layer covering the gate stack (304) and the source/drain regions;
wherein a portion of the channel region near the source region has a thickness 1-3 times that of a portion of the channel region near the drain region.

In the asymmetric super-thin SOIMOS transistor, the portion of the channel region near the source region has a larger width, which may reduce the effects on the career mobility by the channel thickness, and the portion of the channel region near the drain region has a smaller width, which may reduce the effects of DIBL without influence on the career mobility. Compared with the prior art, the present disclosure can suppress the short channel effects and enhance device performance.

### BRIEF DESCRIPTION OF DRAWINGS

After reading the following detailed description of the non-limiting embodiments in connection with the attached drawings, other features, objectives and advantages of the present disclosure will be more apparent.

FIGS. 1-7 are cross-sectional diagrams in respective stage of manufacturing the super-thin SOIMOS device according to one embodiment of the present disclosure.

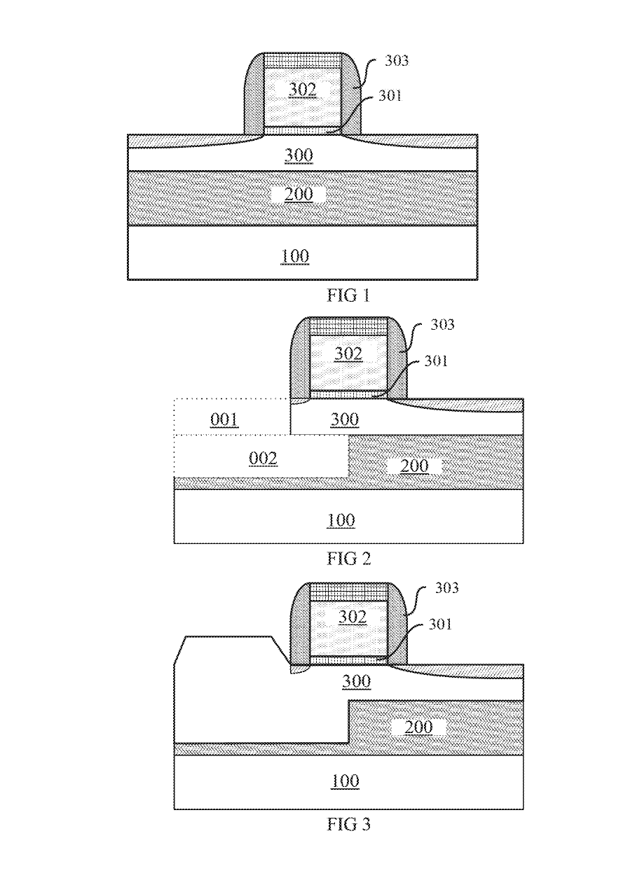

In the drawings, the same or similar reference numbers denote the same or similar components.

### DETAILED EMBODIMENTS

In the following, in order to make objectives, technical solutions and advantages of the present disclosure more clear, embodiments of the present disclosure will be described in detail in connection with the attached drawings.

Hereinafter, embodiments of the present disclosure are described. Examples of the embodiments are shown in the attached drawings. The same or similar reference numbers denote the same or similar elements or elements having the same or similar function throughout the drawings. Embodiments described with reference to the drawings are illustrative only, and are intended to interpret the invention rather than limiting the invention.

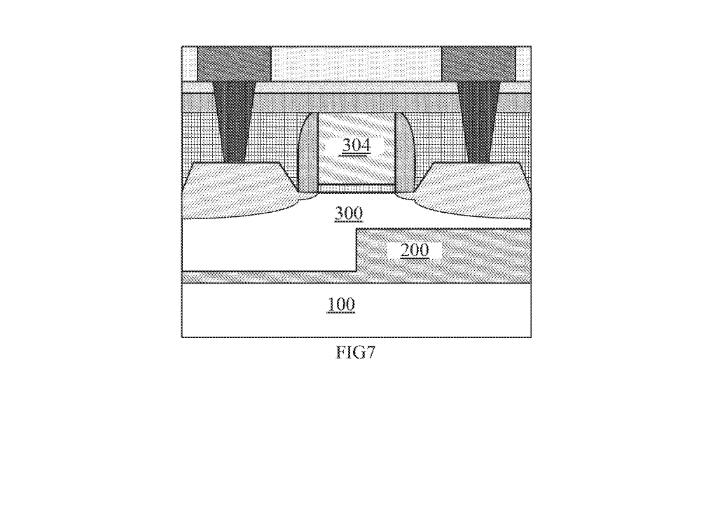

As shown in FIG. 7, an asymmetric super-thin SOIMOS transistor is provided in the present disclosure. The SOIMOS transistor comprises: a substrate 100; an insulating layer 200; a semiconductor layer 300 on the insulating layer 200; a gate dielectric layer 301 on the semiconductor layer 300; a gate stack 304 on the gate dielectric layer 301; a channel region beneath the gate stack 304; source/drain regions on both sides of the gate stack 304 in the substrate; and an interlayer dielectric layer covering the gate stack 304 and the source/drain regions, wherein a portion of the channel region near the source region has a thickness 1-3 times the thickness near the drain region. The thick portion of the channel is ¼-⅔ times the overall channel length.

The substrate is formed of a base layer 100, the insulating layer 200 and the semiconductor layer 300 by SOI manufacturing technique. The SOI manufacturing technique may comprise Separation by IMplanted OXyen (SIMOX), laser recrystallization, bonding and/or Hydrogen implanted Smart-Cut. The SOI substrate may be constructed only by the insulating layer 200 and the semiconductor layer 300, i.e., the base layer 100 is not necessarily formed. The insulating layer 200 is an oxide layer formed on the base layer 100, preferably SiO2, and has a thickness of about 5-200 nm. The semiconductor layer 300 is preferably a thin monocrystalline silicon layer, or may be monocrystalline GeSi, and may have a thickness of about 5-20 nm, for example, 8 nm, 10 nm.

The gate dielectric layer 301 is preferably silicon oxynitride, or may be silicon oxide or high-K materials. The Equivalent Oxide Thickness (EOT) thereof is 0.5-5 nm.

The gate may comprise a conductive gate stack 304 and a pair of insulating dielectric spacers on both sides of the gate stack 304. The gate stack 304 may be a metal gate, or may be a metal/polysilicon composite gate with silicide formed on the polysilicon.

The semiconductor channel region is located on the surface of the insulating layer 200, and may be preferably made of monocrystalline silicon or monocrystalline Germanium alloy thin films with a thickness of about 5-20 nm. The region is lightly doped or un-doped. In case of doped regions, the doping type thereof is opposite to that of the source/drain regions.

The source/drain regions are located on both sides of the gate stack in the semiconductor layer 300 on the insulating layer 200, respectively. The portion of the channel region near the source has a thickness larger than that of the portion near the drain, and may have a thickness of about 10-60 nm.

In the asymmetric super-thin SOIMOS transistor according to one embodiment of the present disclosure, the portion of the channel near the source has a larger width, which may reduce the effect on carrier mobility by the channel width. The portion of the channel near the drain has a smaller width, which may reduce the effect of DIBL without affecting career mobility. Compared with the prior art, the technical solution of the present disclosure may suppress short channel effects and enhance device performance.

Hereafter, the method for manufacturing the SOIMOS transistor according to the present disclosure will be described in detail with references the attached drawings. It should be noted that the drawings of respective examples are illustrative only, and are not drawn to scale.

Firstly, a substrate is provided. The substrate may be made of SOI materials. The SOI material may be prepared by bonding and back-side etching technique, and may be constituted of the base layer 100, the buried oxide layer 200 and the monocrystalline silicon film 300. The buried oxide layer may have a thickness of about 75-200 nm. The monocrystalline silicon film 300 may have a starting thickness of about 5-20 nm, and may be thinned to a desirable thickness by thermal oxidation and BOE corrosion technique in case of excessive thickness. The substrate may also be other insulating materials such as sapphire or glass.

The gate dielectric layer 301 is formed on the substrate. The gate dielectric layer 301 may be a thermal oxidation layer including silicon oxide or silicon oxynitride, or may be high-K dielectrics such as HfAlON, HfSiAlON, HfTaAlON, HfTiAlON, HfON, HfSiON, HfTaON, HfTiON, Al₂O₃, La₂O₃, ZrO₂, or LaAlO, or combinations thereof. The gate dielectric layer 301 may have a thickness of about 1-10 nm, such as 3 nm, 5 nm, or 8 nm. The gate dielectric layer 301 may be formed by thermal oxidation, Chemical Vapor Deposition (CVD), Atom Layer Deposition (ALD), etc.

Next, a dummy gate structure 302 may be formed on the gate dielectric layer 301. The dummy gate structure 302 may be a single-layer or multi-layer structure. The dummy gate structure 302 may comprise polymer, amorphous silicon, polysilicon or TiN, and may have a thickness of about 10-200 nm. In the present embodiment, the dummy gate structure 302 may comprise polysilicon and silicon dioxide. Specifically, polysilicon is filled into vacancies between gates by CVD to have a height substantially lower than the spacer by 10-20 nm. Then, a silicon dioxide layer is formed on the polysilicon by, for example, epitaxial growth, oxidation, CVD, etc. Then, the deposited dummy gate structure 302 is etched by photolithography in conventional CMOS processes to form gate patterns. The exposed portions of the gate dielectric layer 301 is etched off with the gate patterns as a mask. The portions in the semiconductor layer covered by the gate dielectric layer form the channel region of the transistor. It should be noted that, if not stated otherwise, dielectric materials in the present disclosure may be deposited by the same or similar methods as the method for forming the gate dielectric layer described above, and may be omitted herein.

Next, the semiconductor layer 300 on both sides of the dummy gate structure 302 is lightly doped so as to form lightly-doped source/drain regions. Further, halo implantation may be performed to form halo implantation regions. The dopants for light doping have the same type as the device, and the dopants for halo implantation have an opposite type to the device.

Optionally, a spacer 303 may be formed on sidewalls of the gate stack to insulate the gates. Specifically, a sacrificial spacer dielectric layer of silicon nitride is deposited by Low-Pressure CVD (LPCVD) to have a thickness of about 40-80 nm. Then, the spacer 303 of silicon nitride with a width of about 35-75 nm is formed on both sides of the gate by etching back technique. The spacer 303 may also be made of silicon oxide, silicon oxynitride, silicon carbide or combinations thereof, and/or other suitable materials. The spacer 303 may be a multi-layer structure. The spacer 303 may also be formed by processes including deposition and etching, and may have a thickness of about 10-100 nm, such as 30 nm, 50 nm or 80 nm.

Next, the semiconductor material of the semiconductor layer 300 on the source side is removed to form a first vacancy 001. Specifically, the gate dielectric layer and the semiconductor structure on the drain side are covered by a photo resist layer, and the exposed semiconductor 300 on the drain side is anisotropically etched by, for example, dry etching because the semiconductor layer 300 has a thickness of about 5-20 nm. After the etching, the first vacancy 001 is formed. The first vacancy 001 has the same length as that of the source region on the semiconductor layer 300, and has the same thickness as that of the semiconductor layer 300.

Next, the insulating material in the source region and under the channel region near the source region on the insulating layer 200 is removed to form a second vacancy 002. Specifically, the insulating layer 200 under the first vacancy 001 is isotropically etched to form the desired second vacancy 002 by, for example, dry and/or wet etching. The second vacancy 002 has a thickness 1-3 times that of the semiconductor layer 300. The portion of the second vacancy 002 extending to under the gate stack 304 has a length ¼-⅔ times the length of the gate 302. The structure after formation of the second vacancy 002 is shown in FIG. 2.

Next, as shown in FIG. 3, semiconductor materials such as silicon or alloy of germanium and silicon are filled into the first vacancy 001 and the second vacancy 002 by, for example, selective epitaxy. Specifically, mask such as silicon dioxide or silicon oxynitride is formed on the portions of the semiconductor structure except the source region. Monocrystalline silicon or germanium is grown to a desired thickness of the source region by epitaxy with the portion of the channel region near the source above the second vacancy 002 as a seed. Then, the mask is removed by, for example, etching with hydrogen chloride. In order to reduce the parasitic resistance of the source region, the grown semiconductor layer has a thickness higher than the surface before formation of the first vacancy 001 by etching (i.e., bottom of the gate dielectric layer) by 20-100 nm.

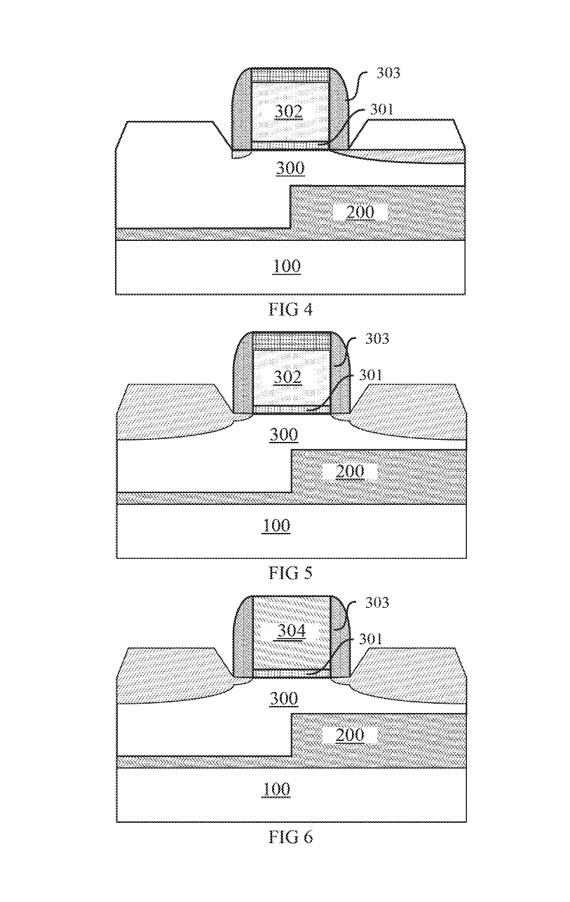

Similarly, as shown in FIG. 4, in order to reduce the parasitic resistance of the drain region, the semiconductor layer 300 on the drain side is thicken preferably by selective epitaxy. Specifically, Monocrystalline silicon or germanium is grown such that the drain region has a thickness flushed with the drain region by epitaxy with the semiconductor layer in the drain region as a seed, or by conventional LPCVD.

After formation of the semiconductor materials in the source/drain regions, a dielectric layer of silicon dioxide is deposited to have a thickness of about 10-35 nm. Then, dopants are implanted into the source/drain regions with the dielectric layer as a buffer layer. For a p-type crystal, the dopants may be B, BF2, In or Ga, and the doping concentration may be 5e10¹⁹ cm⁻³-1e10²⁰ cm⁻³. The semiconductor structure after the doping is shown in FIG. 5.

Next, the dummy gate structure 302 is removed by, for example, dry and/or wet etching, to form a dummy gate vacancy. In one embodiment, the dummy gate structure 302 is removed by plasma etching.

Next, as shown in FIG. 6, a gate stack 304 is formed in the dummy gate vacancy. The gate stack 304 may be a metal gate, or a composite gate of metal/polysilicon with silicide formed on the polysilicon.

Preferably, a work function metal layer is deposited on the gate dielectric layer 301, and then a conductive metal layer is formed on the work function metal layer. The work function metal layer may be formed of TiN, TaN, etc., and may have a thickness of about 3-15 nm. The conductive metal layer may be a single-layer or multi-layer structure, and may be formed of TaN, TaC, TiN, TaAlN, TiAlN, MoAlN, TaTbN, TaErN, TaYbN, TaSiN, HfSiN, MoSiN, RuTaₓ, NiTaₓ, or combinations thereof, and may have a thickness of about 10-40 nm, for example, 20 nm or 30 nm.

Finally, subsequent processes in conventional CMOS technique may be performed, including passive layer deposition, contact hole formation and metallization, etc., so as to form the super-thin SOIMOS transistor, as shown in FIG. 7.

Although the exemplary embodiments and their advantages have been described in detail, it should be understood that various alternations, substitutions and modifications may be made to the embodiments without departing from the spirit of the present invention and the scope as defined by the appended claims. For other examples, it may be easily recognized by a person of ordinary skill in the art that the order of processing steps may be changed without departing from the scope of the present invention.

In addition, the scope to which the present invention is applied is not limited to the process, mechanism, manufacture, material composition, means, methods and steps described in the specific embodiments in the specification. According to the disclosure of the present invention, a person of ordinary skill in the art would readily appreciate from the disclosure of the present invention that the process, mechanism, manufacture, material composition, means, methods and steps currently existing or to be developed in future, which perform substantially the same functions or achieve substantially the same as that in the corresponding embodiments described in the present invention, may be applied according to the present invention. Therefore, it is intended that the scope of the appended claims of the present invention includes these process, mechanism, manufacture, material composition, means, methods or steps.

1. A method for manufacturing an asymmetric super-thin SOIMOS transistor, comprising:
a. providing a substrate composed of an insulating layer (200) and a semiconductor layer (300);
b. forming a gate stack (304) on the substrate;
c. removing semiconductor materials of the semiconductor layer (300) on a source region side to form a first vacancy (001);
d. removing insulating materials of the insulating layer (200) in the source region and under a channel near the source region to form a second vacancy (002);
e. filling semiconductor materials into the first vacancy (001) and the second vacancy (002) to connect with the semiconductor materials above the second vacancy (002); and
f. performing source/drain implantation.

2. The method of claim 1, wherein in step c, the first vacancy (001) has a length equal to that of the source region on the semiconductor layer (300), and has a thickness equal to that of the semiconductor layer (300).

3. The method of claim 1, wherein in step c, the semiconductor materials of the semiconductor layer (300) on a source region side are removed by anisotropic etching to form a first vacancy (001).

4. The method of claim 1, wherein in step d, the second vacancy (002) has a thickness 1-3 times that of the semiconductor layer (300).

5. The method of claim 1, wherein in step d, the length of the vacancy (002) extending into under the gate stack (304) is ¼-⅔ times the length of the gate stack (304).

6. The method of claim 1, wherein in step d, the insulating materials of the insulating layer (200) in the source region and under channel near the source region is removed by isotropic etching to form a second vacancy (002).

7. The method of claim 1, wherein in step e, the semiconductor materials are filled into the first vacancy (001) and the second vacancy (002) by selective epitaxial growth.

8. The method of claim 1, wherein the step b is replaced by:
g. forming a gate dielectric layer (301) on the substrate, and forming a dummy gate structure (302) on the gate dielectric layer (301); and
h. forming source/drain extension regions on both sides of the dummy gate stack (302).

9. The method of claim 1, wherein after the step f, the method further comprises:
i. thickening the semiconductor layer (300) on the drain region side such that the top of the drain region is flushed with the top of the source region.

10. The method of claim 8, wherein after the step f, the method further comprises:
j. removing the dummy gate stack (302) to form a dummy gate vacancy; and
k. depositing the gate stack (304) in the dummy gate vacancy.

11. An asymmetric super-thin SOIMOS transistor, comprising:
a. a substrate (100);
b. an insulting layer (200) on the substrate (100);
c. a semiconductor layer (300) on the insulting layer (200);
d. a gate dielectric layer (301) on the semiconductor layer (300);
e. a gate stack (304) on the gate dielectric layer (301);
f. a channel region under the gate stack (304);
g. source/drain regions in the substrate on both sides of the gate stack (304); and
h. an interlayer dielectric layer covering the gate stack (304) and the source/drain regions;
i. wherein a portion of the channel region near the source region has a thickness 1-3 times that of a portion of the channel region near the drain region.

12. The asymmetric super-thin SOIMOS transistor of claim 11, wherein the thick portion of the channel region is ¼-⅔ times the total length of the channel region.
